(19) United States
(12) Patent Application Publication
(10) Pub. No.: US 2026/0324112 A1
(43) Pub. Date: Oct. 15, 2026

(54) IMAGE SENSOR

(71) Applicant: SAMSUNG ELECTRONICS CO., LTD., Suwon-si (KR)

(72) Inventors: FUJITA MASATO, Suwon-si (KR); SEUNGKI JUNG, Suwon-si (KR)

(73) Assignee: SAMSUNG ELECTRONICS CO., LTD., Suwon-si (KR)

(21) Appl. No.: 19/638,773

(22) Filed: Apr. 3, 2026

(30) Foreign Application Priority Data
Apr. 11, 2025 (KR) 10-2025-0047615

(51) Int. Cl. H10F 39/00

(52) U.S. Cl. CPC H10F 39/8057; H10F 39/802; H10F 39/8037; H10F 39/807; H10F 39/811

(57) ABSTRACT

An image sensor includes a substrate including a plurality of photoelectric conversion regions, a separation pattern between the plurality of photoelectric conversion regions and separating the substrate, a plurality of active patterns on the substrate, a plurality of gate patterns overlapping the plurality of active patterns, a connection contact connected to the plurality of active patterns or the gate pattern, a dummy gate pattern overlapping the separation pattern, and a shield contact connected to the dummy gate pattern, wherein the shield contact and the connection contact are in parallel in a first direction.

### CROSS-REFERENCE TO RELATED APPLICATION

This application claims priority under 35 U.S.C. § 119 to and the benefit of Korean Patent Application No. 10-2025-0047615, filed on Apr. 11, 2025, in the Korean Intellectual Property Office , the disclosure of which is incorporated herein by reference in its entirety.

### BACKGROUND

### Field

The disclosure relates generally to an image sensor with a separation pattern.

### Description of the Related Art

An image sensor is a semiconductor device that converts an optical image into an electrical signal. The image sensor may be classified into charge coupled device (CCD) type and complementary metal oxide semiconductor (CMOS) type. The CMOS type image sensor is referred to as CMOS image sensor (CIS). The CIS includes a plurality of pixels arranged two-dimensionally. Each pixel includes a photodiode that converts incident light into an electrical signal.

### SUMMARY

The disclosure provides an image sensor that reduces coupling between neighboring pixels and may be driven by various combinations of conversion gains.

An image sensor according to an embodiment includes a substrate including a plurality of photoelectric conversion regions, a separation pattern between the plurality of photoelectric conversion regions and separating the substrate, a plurality of active patterns on the substrate, a plurality of gate patterns overlapping the plurality of active patterns, a connection contact connected to the plurality of active patterns or the plurality of gate patterns, a dummy gate pattern overlapping the separation pattern, and a shield contact connected to the dummy gate pattern, wherein the shield contact and the connection contact are arranged in parallel in a first direction.

According to another embodiment, an image sensor includes a substrate, a plurality of pixels on the substrate and separated by a separation pattern, the pixels including a plurality of photoelectric conversion regions, a plurality of transfer transistors connected to the plurality of photoelectric conversion regions, a dummy transistor having a gate electrode configured to receive a ground voltage, and a shield contact connected to the gate electrode of the dummy transistor, the shield contact overlaps a separation pattern between the plurality of pixels.

According to another embodiment, an image sensor includes a substrate including a photoelectric conversion region, a plurality of transistors on the substrate and including dummy transistors, a connection contact connected to the plurality of transistors, and a shield contact connected to a gate electrode of each dummy transistor, wherein the shield contact is configured to apply a ground voltage to the gate electrode of each dummy transistor, and the connection contact and the shield contact are arranged in parallel in a direction.

According to embodiments, it provides an image sensor that reduces coupling between neighboring pixels and may be driven by various combinations of conversion gains.

### BRIEF DESCRIPTION OF DRAWINGS

FIG. 1 is a block diagram of an image sensor according to an embodiment.

FIG. 2 is a circuit diagram of a pixel included in an image sensor according to embodiments.

FIG. 3 illustrates a circuit diagram of a pixel according to another embodiment.

FIG. 4 shows a circuit diagram of a pixel according to yet another embodiment.

FIG. 5 is a top plan view showing an image sensor including a pixel according to an embodiment.

FIG. 6 illustrates the planar shape of the pixel shown in FIG. 5.

FIG. 7 is a cross-sectional view taken along line A-A' of FIG. 6.

FIG. 8 is a cross-sectional view taken along line B-B' of FIG. 6.

FIG. 9 is a cross-sectional view taken along line C-C' of FIG. 6.

FIG. 10 is a simplified three-dimensional drawing of the structure of region R1 of FIG. 6.

FIG. 11 is an enlarged view of region R2 of FIG. 6.

FIG. 12 to FIG. 18 illustrate the region R2 of FIG. 11 in an image sensor in another embodiment.

FIG. 19 illustrates region R3 of FIG. 6 of an image sensor according to another embodiment.

FIG. 20 is a cross-section of FIG. 19 taken along line D-D'.

FIG. 21 illustrates the same region as FIG. 20 for another embodiment.

FIG. 22 is a cross-sectional view taken along line E-E' of FIG. 6.

### DETAILED DESCRIPTION

Hereinafter, with reference to the accompanying drawing, various embodiments are described in detail so that a person of ordinary skill in the art may readily practice the invention. The disclosure may be implemented in many different forms and is not limited to the embodiments described herein.

In order to clearly explain the disclosure, parts that are not related to the description have been omitted, and the same reference symbols are used for identical or similar components throughout the specification.

In addition, the size and thickness of each component shown in the drawing are arbitrarily shown for descriptive convenience, so the disclosure is not necessarily limited to what is shown. In the drawings, the thickness of layers, films, panels, regions, etc., are exaggerated for clarity. In the drawing, for descriptive convenience, the thickness of some layers and regions is exaggerated.

Additionally, It will be understood that when an element such as a layer, film, region, or substrate is referred to as being “on” another element, it may be directly on the other element or intervening elements may also be present. In contrast, when an element is referred to as being “directly on” another element, there are no intervening elements present. Also, being “above” or “on” the referenced part means being positioned above or below the referenced part, and does not necessarily mean being positioned “above” or “on” the opposite direction of gravity.

Additionally, unless explicitly described to the contrary, the word “comprise”, and variations such as “comprises” or “comprising”, will be understood to imply the inclusion of stated elements but not the exclusion of any other elements.

Also, throughout the specification, when we say “in plan”, we mean when the target portion is viewed from above, and when we say “in cross-section”, we mean when the target portion is viewed from the side in a cross-section cut vertically.

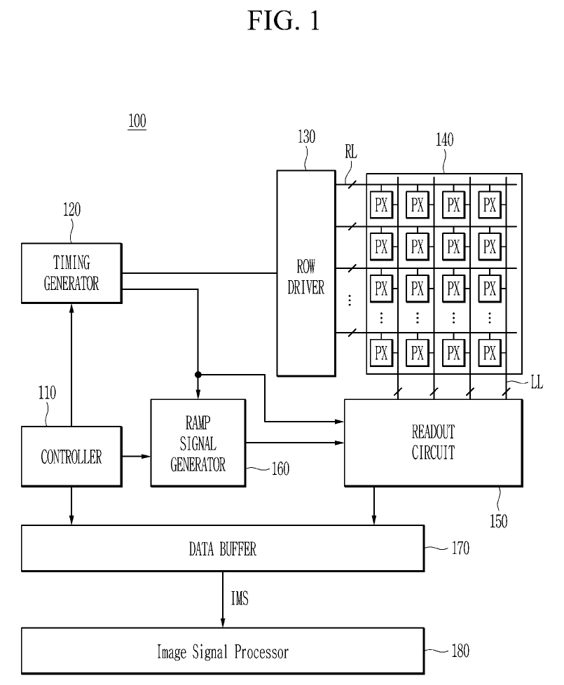

FIG. 1 is a block diagram of an image sensor 100 according to an embodiment.

Referring to FIG. 1, the image sensor 100 according to an embodiment may include a controller 110, a timing generator 120, a row driver 130, a pixel array 140, a readout circuit 150, a ramp signal generator 160, a data buffer 170, and an image signal processor 180. In another embodiment, the image signal processor 180 may be positioned outside the image sensor 100.

The image sensor 100 may convert light received from the outside into an electrical signal to generate an image signal IMS. The image signal IMS may be provided to the image signal processor 180.

The image sensor 100 may be mounted on an electronic device that performs an image sensing function or a light sensing function. For example, the image sensor 100 may be mounted on electronic devices such as a camera, a smartphone, a wearable device, an Internet of Things (IoT) device, a home appliance, a tablet personal computer (PC), a personal digital assistant (PDA), a portable multimedia player (PMP), a navigation device, a drone, an advanced driver assistance system (ADAS), and the like. In another example, the image sensor 100 may be mounted on an electronic device provided as a component in a vehicle, furniture, manufacturing equipment, doors, or various measuring instruments.

The controller 110 may control components (e.g., 120, 130, 150, 160, 170) included in the image sensor 100. The controller 110 may also control the operation timing of each component (e.g., 120, 130, 150, 160, 170) using control signals. In an embodiment, the controller 110 may receive a mode signal indicating an imaging mode from an application processor, and may control the image sensor 100 based on the received mode signal. For example, the application processor may determine the imaging mode of the image sensor 100 according to various scenarios, such as illumination of an imaging environment, a resolution setting of a user, and a sensing or learned status, and provide the determined result to the controller 110 as a mode signal. The controller 110 may control a plurality of pixels of the pixel array 140 to output the pixel signals according to a capturing mode, the pixel array 140 may output the pixel signals for each of the plurality of pixels or the pixel signals for some of the plurality of pixels, and the readout circuit 150 may sample and process the pixel signals received from the pixel array 140. The timing generator 120 may generate signals that serve as references for the operation timing of the components of the image sensor 100. The timing generator 120 may control the timing of the row driver 130, the readout circuit 150, and the ramp signal generator 160. The timing generator 120 may provide control signals to control the timing of the row driver 130, readout circuit 150, and the ramp signal generator 160.

The pixel array 140 may include a plurality of pixels PX, and a plurality of row lines RL and a plurality of column lines LL each connected to a plurality of pixels PX. In an embodiment, each pixel PX may include at least one or more photoelectric conversion devices. The photoelectric conversion device may detect incident light and convert the incident light into an electrical signal (e.g., an analog pixel signal) based on the amount of light . The photoelectric conversion device may be a photodiode, a pinned diode, etc. For example, the photoelectric conversion device may be a Single-Photon Avalanche Diode (SPAD) applied to a three-dimensional (3D) sensor pixel. The level of the analog pixel signal output from the photoelectric conversion device may be proportional to the amount of charge output from the photoelectric conversion device. For example, the level of the analog pixel signal output from the photoelectric conversion device may be determined according to the amount of light received in the pixel array 140.

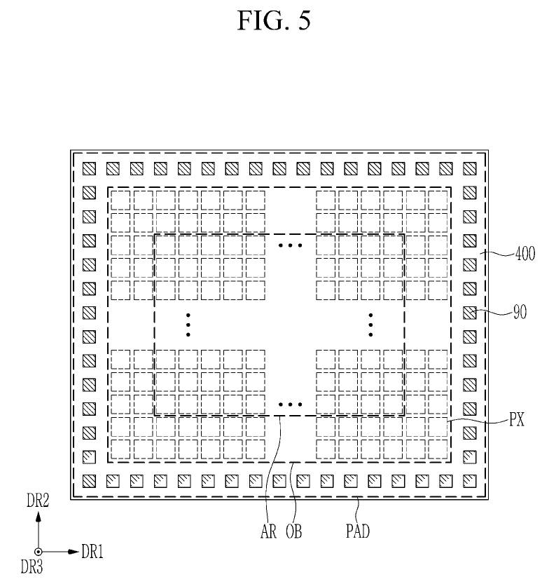

The plurality of row lines RL extend in a first direction (e.g., DR1 in FIG. 5) and may be connected to a plurality of pixels PX arranged along the first direction (e.g., DR1 in FIG. 5). For example, a control signal output from the row driver 130 to the row line RL may be transmitted to a gate of a transistor of the plurality of pixels PX connected to the corresponding row line RL. A plurality of column lines LL may extend in a second direction (e.g., DR2 in FIG. 5) intersecting the first direction (e.g., DR1 in FIG. 5) and may be connected to pixels PX arranged along the second direction (e.g., DR2 in FIG. 5). The plurality of pixel signals output from a plurality of pixels PX may be transmitted to the readout circuit 150 through the plurality of column lines LL.

A color filter layer and a micro lens layer may be positioned on top of the pixel array 140. The micro lens layer may include a plurality of micro lenses, and each of the plurality of micro lenses may be positioned on top of a corresponding pixel PX. The color filter layer may include color filters such as red, green, and blue filters, and may additionally include a white color filter. In the pixel (e.g., single pixel) PX, a color filter of a certain color may be positioned between the pixel PX and the corresponding micro lens. In another example, the color filter of the certain color may be positioned on the plurality of pixels PX that represent the same color.

The row driver 130 may generate a control signal for driving the pixel array 140 in response to a control signal of the timing generator 120, and may provide the control signal to the plurality of pixels PX of the pixel array 140 through the plurality of row lines RL. In an embodiment, the row driver 130 may control the pixel PX to detect light incident on the row line unit. A row line unit may include at least one row line RL. For example, the row driver 130 may provide a transmit signal, a reset signal, a selection signal, etc. to pixel array 140 as described below.

The readout circuit 150 may convert the pixel signals (e.g., electrical signals) from pixels PX connected to a selected row line RL among the plurality of pixels PX into pixel values indicating the amount of light in response to the control signal from the timing generator 120. The readout circuit 150 may convert the pixel signal output from the corresponding column line LL into a pixel value. For example, the readout circuit 150 may convert the pixel signal into the pixel value by comparing the ramp signal and the pixel signal. The pixel value may be image data with multiple bits. For example, the readout circuit 150 may include a selector, a plurality of comparators, and a plurality of counter circuits.

The ramp signal generator 160 may generate a reference signal and transmit the reference signal to the readout circuit 150.

The ramp signal generator 160 may include a current source, a resistor, and a capacitor. The ramp signal generator 160 may generate a plurality of ramp signals that rise or fall with a slope determined by the current amount of a variable current source or the resistance value of a variable resistor by controlling the ramp voltage, which is a voltage applied to the lamp resistor, by controlling the current amount of the variable current source or by controlling the resistance value of the variable resistor. Thus, the slopes of the generated ramp signals may be varied by the ramp signal generator 160.

The data buffer 170 may store the pixel values of the plurality of pixels PX connected to a selected column line LL, which are transmitted from the readout circuit 150, and may output the stored pixel values in response to an enable signal from the controller 110.

The image signal processor 180 may perform image signal processing on image signals received from the data buffer 170. For example, the image signal processor 180 may receive a plurality of image signals from the data buffer 170 and synthesize the received image signals to generate an image.

In an embodiment, the plurality of pixels PX may be grouped in the form of a M*N format (here, M and N are integers greater than or equal to 2) to form a single unit pixel group. The M*N format may be a format in which M pixels are listed in a direction and N pixels are listed in a row direction. For example, a unit pixel group (e.g., single unit pixel group) may include a plurality of pixels arranged in a 2*2 format, and the unit pixel group may output an analog pixel signal (e.g., single analog pixel signal). The following embodiment is not limited to a single pixel, but may also be applied to a group of unit pixels.

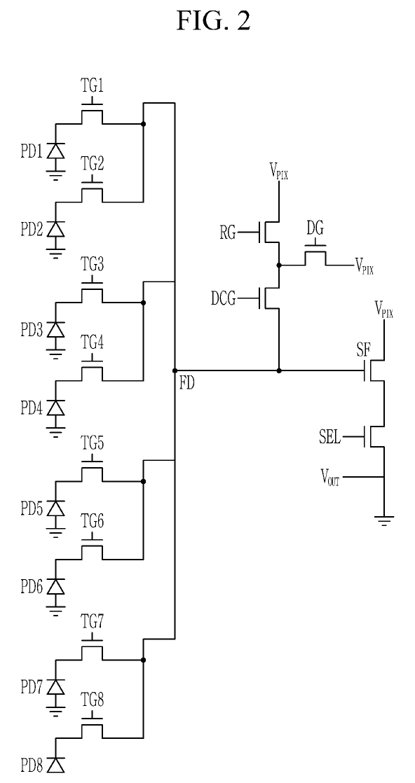

FIG. 2 is a circuit diagram of a pixel included in an image sensor according to embodiments.

Referring to FIG. 2, a pixel PX may include a plurality of photoelectric conversion devices PD1, PD2, PD3, PD4, PD5, PD6, PD7, and PD8. Each photoelectric conversion device PD1, PD2, PD3, PD4, PD5, PD6, PD7, and PD8 may perform photoelectric conversion. As shown in FIG. 2, a plurality of photoelectric conversion devices PD1, PD2, PD3, PD4, PD5, PD6, PD7, and PD8 may be connected to a floating diffusion region (e.g., single floating diffusion region) FD. FIG. 2 illustrates a configuration in which eight photoelectric conversion devices are connected to the single floating diffusion region FD, but this is an example, and the plurality of photoelectric conversion devices connected to the single floating diffusion region FD may vary according to embodiments.

The following description focuses on the first photoelectric conversion device PD1, but the following description applies equally to other photoelectric conversion devices PD2, PD3, PD4, PD5, PD6, PD7, and PD8.

The first photoelectric conversion device PD1 may generate and accumulate charge according to the amount of incident light. The first photoelectric conversion device PD1 may include an anode connected to ground (e.g., 0 V) and a cathode connected to a first end portion of the first transmission transistor TG1. The first transmission signal may be supplied to the gate of the first transmission transistor TG1, and a second end portion of the first transmission transistor TG1 may be connected to the floating diffusion region FD. When the first transmission transistor TG1 is turned on by the first transmission signal, the charge stored in the first photoelectric conversion device PD1 may be transferred to the floating diffusion region FD. The floating diffusion region FD may retain the charge transferred from the plurality of photoelectric conversion devices PD1, PD2, PD3, PD4, PD5, PD6, PD7, and PD8.

Each of the plurality of transmission transistors TG1, TG2, TG3, TG4, TG5, TG6, TG7, and TG8 may be connected between one of the plurality of photoelectric conversion devices PD1, PD2, PD3, PD4, PD5, PD6, PD7, and PD8 and the floating diffusion region FD, and may include a gate electrode receiving a plurality of transmission signals. The number of the plurality of transmission transistors TG1, TG2, TG3, TG4 ,TG5, TG6, TG7, and TG8 may be equal to the number of the plurality of photoelectric conversion devices PD1, PD2, PD3, PD4, PD5, PD6, PD7, and PD8.

A reset transistor RG may be connected between the power source voltage Vpix and the floating diffusion region FD and may include a gate electrode that receives a reset signal.

The reset transistor RG may periodically reset the charges accumulated in the floating diffusion region FD. The drain electrode of the reset transistor RG may be connected to a source electrode of a dual conversion transistor DCG, and the source electrode may be connected to the power source voltage Vpix. When the reset transistor RG is turned on, the power source voltage Vpix connected to the source electrode of the reset transistor RG may be applied to the floating diffusion region FD. Therefore, when the reset transistor RG is turned on, the charges accumulated in the floating diffusion region FD may be discharged, so that the floating diffusion region FD may be reset.

The dual conversion transistor DCG may be positioned between the reset transistor RG and the floating diffusion region FD and may include a gate electrode that receives a dual conversion signal. The dual conversion transistor DCG may reset the floating diffusion region FD together with the reset transistor RG.

The drain electrode of the dual conversion transistor DCG may be connected to the floating diffusion region FD, and the source electrode of the dual conversion transistor DCG may be connected to the drain electrode of the reset transistor RG. When the reset transistor RG and the dual conversion transistor DCG are turned on, the power source voltage Vpix connected to the source electrode of the reset transistor RG may be applied to the floating diffusion region FD through the dual conversion transistor DCG. Therefore, the charges accumulated in the floating diffusion region FD may be discharged, and the floating diffusion region FD may be reset.

As shown in FIG. 2, the dummy transistor DG may be positioned between the reset transistor RG and the dual conversion transistor DCG. A ground voltage may be applied to a gate electrode of the dummy transistor DG, a first electrode of the dummy transistor DG may be connected between the reset transistor RG and the dual conversion transistor DCG, and a second electrode may receive a power source voltage Vpix.

The dummy transistor DG may act as an additional capacitor connected to the floating diffusion region FD. For example, an overlap capacitance Cov may be formed between the source/drain region of the dummy transistor DG and the gate electrode DRG of the dummy transistor DG to which the ground voltage is applied. The image sensor 100 according to an embodiment may effectively implement different conversion gains by using the overlap capacitance Cov.

The image sensor 100 according to an embodiment may selectively use different conversion gains according to the operating mode, and may operate in a high conversion gain (HCG) mode, which provides high sensitivity when a small amount of charge is accumulated, and in a low conversion gain (LCG) mode, which is suitable when a large amount of charge is accumulated. However, in the LCG mode, a relatively large capacitance may be required.

For example, additional capacitance may be provided by adding a dummy transistor DG including a gate electrode DRG to which the ground voltage is applied. When the ground voltage is applied to the gate electrode DRG of the dummy transistor DG having a metal–oxide–semiconductor field-effect transistor (MOSFET) structure, the overlap capacitance Cov may be formed between the source/drain region of the dummy transistor DG and the gate electrode. Therefore, the overlap capacitance Cov may be used as additional capacitance to improve the entire capacitance of the image sensor 100. The image sensor 100 according to an embodiment relates to the arrangement of these dummy transistors DG, and the specific structure will be described separately later.

The source follower transistor SF may output the pixel signal according to the voltage of the floating diffusion region FD. The gate of the source follower transistor SF may be connected to the floating diffusion region FD, the source electrode of the source follower transistor SF may be connected to an end portion of the selection transistor SEL, and the power source voltage Vpix may be supplied to the drain electrode of the source follower transistor SF. The source follower transistor SF may form a source follower circuit and may output a voltage corresponding to the charge accumulated in the floating diffusion region FD as a pixel signal.

When the selection transistor SEL is turned on by a selection signal, the pixel signal from the source follower transistor SF may be transmitted to the readout circuit. The selection signal may be applied to a gate electrode of the selection transistor SEL, and the drain electrode of the selection transistor SEL may be connected to an output wire Vout that outputs the plurality of pixel signals.

Referring to FIG. 2, the operation of the image sensor 100 is described as follows. First, a power source voltage Vpix may be applied to the drain electrode of the reset transistor RG and the drain electrode of the source follower transistor SF while the light is blocked, and the reset transistor RG and the dual conversion transistor DCG may be turned on to release charges remaining in the floating diffusion region FD. After that, when the reset transistor RG is turned off and external light is incident on the photoelectric conversion devices PD1, PD2, PD3, PD4, PD5, PD6, PD7, and PD8, electron-hole pairs may be generated in each of the photoelectric conversion devices PD1, PD2, PD3, PD4, PD5, PD6, PD7, and PD8. Holes move to and accumulate in the p-type impurities region of the photoelectric conversion device PD1, PD2, PD3, PD4, PD5, PD6, PD7, and PD8, and electrons move to and accumulate in the n-type region. When the transmission transistors TG1, TG2, TG3, TG4, TG5, TG6, TG7, and TG8 are turned on, these charges such as electrons and holes may be transferred to the floating diffusion region FD and accumulated. The gate bias of the source follower transistor SF may be changed in proportion to the amount of accumulated charge, which causes a change in the source potential of the source follower transistor SF. For example, when the selection transistor SEL is turned on, a signal due to charge may be read out through the output wire Vout.

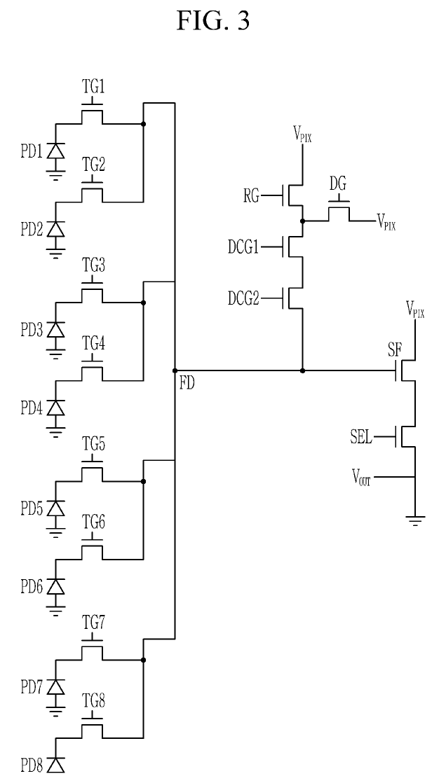

FIG. 2 illustrates a case where the image sensor 100 includes one dual conversion transistor DCG, but in another embodiment, more than one dual conversion transistor DCG may be positioned. FIG. 3 illustrates a circuit diagram of a pixel according to another embodiment. Referring to FIG. 3, the image sensor 100 according to an embodiment is substantially identical to the embodiment of FIG. 2 except that it includes a first dual conversion transistor DCG1 and a second dual conversion transistor DCG2. Redundant descriptions of the same components are omitted. Referring to FIG. 3, the image sensor 100 according to the embodiment of FIG. 3 may implement various conversion gains compared to FIG. 2. For example, when both the first dual conversion transistor DCG1 and the second dual conversion transistor DCG2 are turned off, the floating diffusion region FD may have the minimum capacitance corresponding to the HCG mode, when both the first dual conversion transistor DCG1 and the second dual conversion transistor DCG2 are turned on, the floating diffusion region FD may have the maximum capacitance corresponding to the LCG mode, and when one dual conversion transistor is turned on and another dual conversion transistor is turned off, the floating diffusion region FD may have a capacitance between the HCG mode and the LCG mode, i.e., a medium conversion gain (MCG) mode. For example, a dummy transistor DG may be positioned between the reset transistor RG and the first dual conversion transistor DCG1. The operation of the dummy transistor DG is the same as that described in FIG. 2, so a detailed description of the same component is omitted. For example, the ground voltage may be applied to the gate electrode DRG of the dummy transistor DG, a first electrode of the dummy transistor DG may be connected between the reset transistor RG and the dual conversion transistor DCG, and a second electrode may receive the power source voltage Vpix. As described above, the dummy transistor DG may act as an additional capacitor of the image sensor 100, increasing the entire capacitance of the image sensor 100 and enabling implementation of various combinations of conversion gains.

FIG. 3 illustrates a configuration in which the dummy transistor DG is positioned between the reset transistor RG and the first dual conversion transistor DCG1, but this is an example, and the position of the dummy transistor DG is not limited thereto.

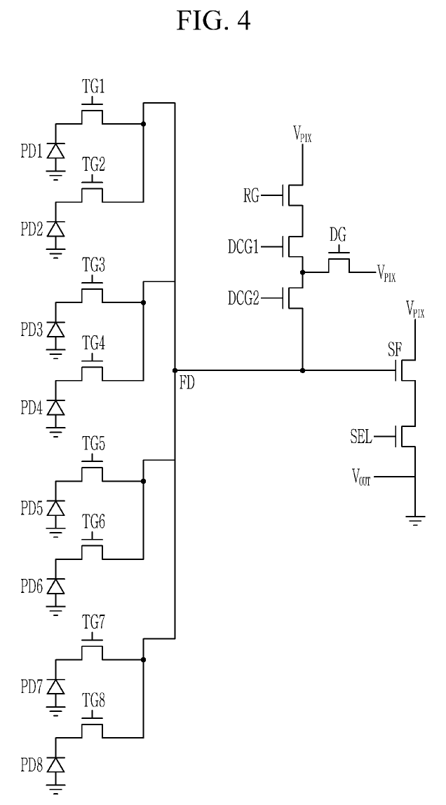

FIG. 4 illustrates a circuit diagram of a pixel according to yet another embodiment. Referring to FIG. 4, the image sensor 100 according to the embodiment is substantially identical to the embodiment of FIG. 3 except that the dummy transistor DG is positioned between the first dual conversion transistor DCG1 and the second dual conversion transistor DCG2. Redundant descriptions of the same components are omitted.

FIG. 5 is a top plan view showing an image sensor according to an embodiment.

Referring to FIG. 5, the substrate 400 may include the pixel array region AR, an optical black region OB, and a pad region PAD. The pixel array region AR may be positioned in the central region of the substrate 400 in a plan view. The pixel array region AR may include a plurality of pixels PX. Each pixel PX may output a photoelectric signal from incident light. The plurality of pixels PX may be arranged along rows parallel to the first direction DR1 and columns parallel to the second direction DR2.

The pad region PAD may be positioned at the edge of the substrate 400 and may surround the pixel array region AR. A plurality of pad terminals 90 may be positioned in the pad region PAD. The plurality of pad terminals 90 may output electrical signals generated from the plurality of pixels PX to the outside. In another example, external electrical signals or voltages may be transmitted to the plurality of pixels PX through the pad terminal 90. The pad region PAD may be positioned at the edge of the substrate 400, so that the pad terminal 90 may be readily connected to the outside.

The optical black region OB may be positioned placed between the pixel array region AR and the pad region PAD of the substrate 400.

The optical black area OB may surround the pixel array region AR. The pixel PX positioned in the optical black region OB may include a dummy region instead of the photoelectric conversion region 410. The signal generated in the dummy region may be used as information for removing or minimizing process noise.

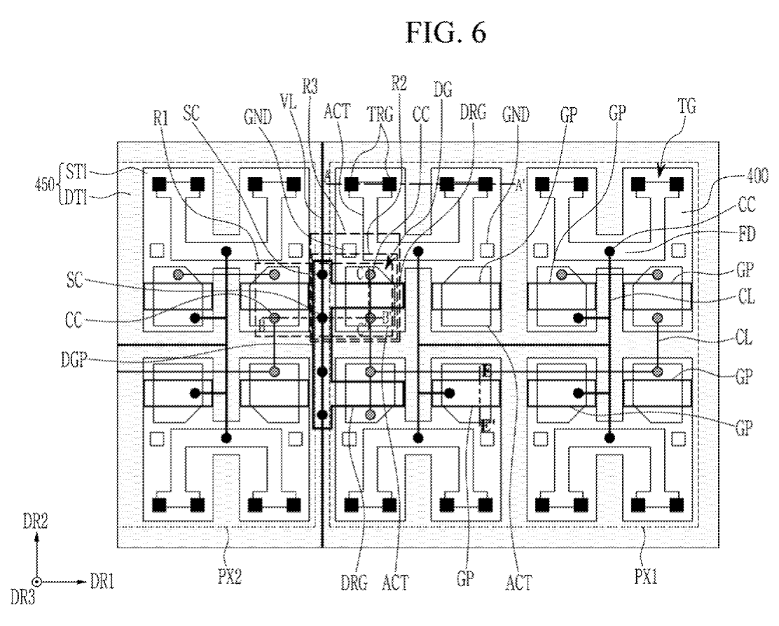

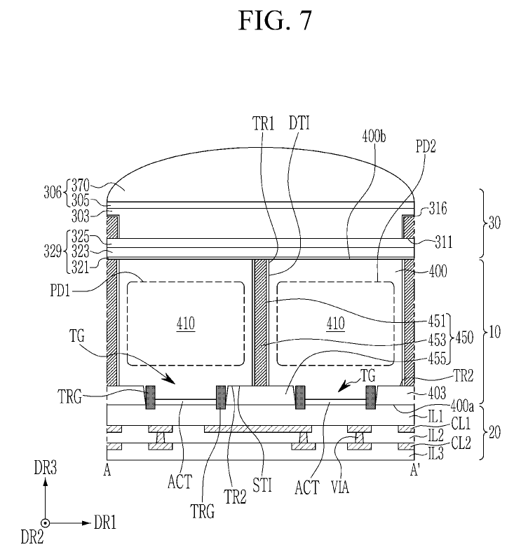

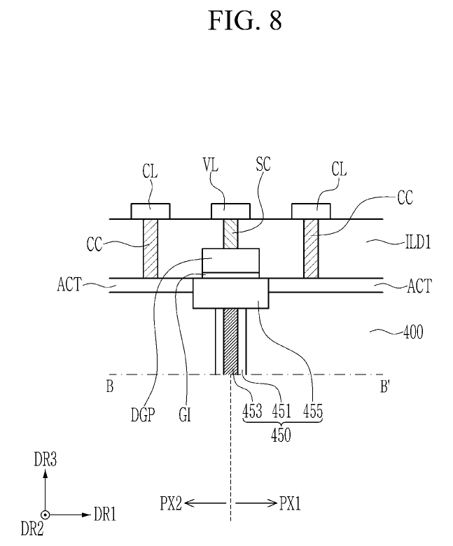

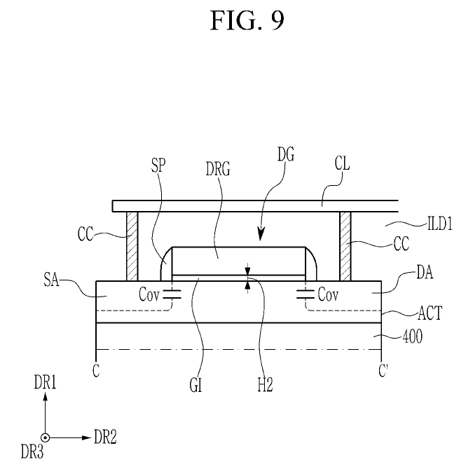

FIG. 6 illustrates the planar shape of the pixel PX shown in FIG. 5. FIG. 6 shows a first pixel area PX1 and part of a second pixel area PX2 neighboring the first pixel area PX1. FIG. 7 is a cross-sectional view taken along line A-A' of FIG. 6. FIG. 8 is a cross-sectional view taken along line B-B' of FIG. 6. FIG. 9 is a cross-sectional view taken along line C-C' of FIG. 6.

Below, the stacking structure and planar arrangement of the image sensor 100 according to the embodiment are described with reference to FIG. 6 to FIG. 8.

First, the planar shape of the image sensor 100 according to the embodiment is described with reference to FIG. 6. Referring to FIG. 6, a plurality of pixel areas may be positioned on substrate 400. FIG. 6 shows part of the first pixel area PX1 and the second pixel area PX2. The parts indicated by dotted lines in FIG. 6 correspond to the first pixel area PX1 and the second pixel area PX2, respectively. For example, in this specification, pixel area means a region where a pixel is positioned as shown in FIG. 2 to FIG. 4.

The image sensor 100 according to an embodiment may include a separation pattern 450. The separation pattern 450 may include a deep trench isolation layer DTI and a shallow trench isolation layer STI. The image sensor 100 may include active patterns ACT and ground patterns GND positioned on the substrate 400. FIG. 6 illustrates the active patterns ACT and the ground patterns GND. The ground patterns GND may be a region where ground voltage is applied, and may be a region where the substrate 400 is doped with the first conductivity type impurity.

Referring to FIG. 6, the gate pattern GP may be positioned on the active pattern ACT. The gate pattern GP may include polycrystalline silicon. However, the disclosure is not limited thereto. FIG. 6 illustrates some gate patterns GPs, and the actual arrangement of the gate patterns GPs is not limited thereto.

Each active pattern ACT and each gate pattern GP overlapping each active pattern ACT may form a transistor. For example, the gate pattern GP overlapping each active pattern ACT may form a reset transistor RG, the dual conversion transistor DCG, and the source follower transistor SF as shown in FIG. 2 to FIG. 4, or a selection transistor SEL.

For example, the gate electrode TRG of the transfer transistor TG may be positioned on the substrate 400. In FIG. 6, the gate electrode TRG of the transmission transistor TG is illustrated as having two gate electrodes, but this is an example and the disclosure is not limited to this. For example, in FIG. 6, the transmission transistor TG is illustrated as a configuration including two gate electrodes TRG spaced apart from each other, which effectively transfer the charge formed in the photoelectric conversion region to the floating diffusion region FD. However, this is an example and the transmission transistor TG may also include one gate electrode TRG.

Referring to FIG. 6, a dummy gate pattern DGP and the gate pattern GP may be positioned in the same layer or at the same level. The dummy gate pattern DGP may be positioned to overlap the separation pattern 450 positioned between the first pixel area PX1 and the second pixel area PX2. As shown in FIG. 6, the dummy gate pattern DGP may be positioned between the first pixel area PX1 and the second pixel area PX2.

Referring to FIG. 6, the dummy gate pattern DGP may include an extension protruded in the first direction DR1. These extensions may form a dummy gate electrode DRG. The dummy gate electrode DRG may be positioned to overlap an active pattern ACT, and the dummy gate electrode DRG and the active pattern ACT overlapping the dummy gate electrode DRG may form the dummy transistor DG.

Referring to FIG. 6, each active pattern ACT and gate pattern GP may be connected to each other through a connection contact CC and a connection wire CL. As shown in FIG. 6, the floating diffusion region FD of each transmission transistor TG may be connected together through the connection contact CC and the connection wire CL. For example, other transistors may be connected together through the connection contact CC and the connection wire CL to form a pixel circuit as shown in FIG. 2 to FIG. 5. FIG. 6 illustrates the connection between the active pattern ACT and the gate pattern GP, but this is an example and the disclosure is not limited thereto.

Referring to FIG. 6, the dummy gate pattern DGP may be connected to the voltage wire VL through a shield contact SC. As shown in FIG. 6, the shield contact SC may be positioned parallel to the connection contact CC in the first direction DR1. As shown in FIG. 6, the shield contact SC may be positioned on a virtual straight line connecting the connection contact CC positioned in the first pixel area PX1 and the connection contact CC positioned in the second pixel area PX2. As will be explained separately later, the shield contact SC may prevent coupling between neighboring pixels while applying the ground voltage to the dummy transistor DG. The specific effects will be described separately later.

Then, the cross-sectional structure of the image sensor 100 according to the embodiment is described below with reference to FIG. 6 to FIG. 9.

Referring to FIG. 6 to FIG. 9, the image sensor 100 according to an embodiment may include a substrate 400. The substrate 400 may include a first surface 400a and a second surface 400b facing each other. Light may be incident on the second surface 400b of the substrate 400. A first wire region 20 may be positioned on/under the first surface 400a of the substrate 400, and the light transmitting layer 30 may be positioned on/over the second surface 400b of the substrate 400. The substrate 400 may be a semiconductor substrate or a silicon on insulator (SOI) substrate. For example, the semiconductor substrate may include a silicon substrate, a germanium substrate, or a silicon-germanium substrate. The substrate 400 may include impurities of the first conductivity type. For example, the first conductivity type impurities may be p-type impurities such as aluminum (Al), boron (B), indium (In), and/or gallium (Ga).

The substrate 400 may include the separation pattern 450. The separation pattern 450 may partition (or separate) a plurality of unit pixels and the plurality of photoelectric conversion regions 410 in each pixel PX. FIG. 7 shows a portion of a cross-section of a pixel PX, showing two photoelectric conversion regions 410 in the cross-section. However, this is a cross-section for descriptive convenience and the disclosure is not limited to this. For example, as shown in FIG. 6, the pixel PX may include eight photoelectric conversion regions 410. However, the disclosure is not limited thereto, and the number of the photoelectric conversion regions 410 included in the pixel PX may vary.

The substrate 400 may include the plurality of photoelectric conversion regions 410. Each photoelectric conversion region 410 may perform the same function and role as the photoelectric conversion devices PD1, PD2, PD3, PD4, PD5, PD6, PD7, and PD8 illustrated in FIG. 2 to FIG. 5. FIG. 7 shows the first photoelectric conversion device PD1 and the second photoelectric conversion device PD2.

The photoelectric conversion region 410 may be a region doped with the second conductivity type impurities in the substrate 400. The second conductivity type impurities may have a conductivity type opposite to the first conductivity type impurities. The second conductivity type impurities may be n-type impurities such as phosphorus (P), arsenic (As), bismuth (Bi), and antimony. For example, each photoelectric conversion region 410 may include a first region adjacent to the first surface 400a and a second region adjacent to the second surface 400b. There may be a difference in impurity concentration between the first region and the second region of the photoelectric conversion region 410. Therefore, the photoelectric conversion region 410 may have a potential slope between the first surface 400a and the second surface 400b of the substrate 400. However, in another example, the photoelectric conversion region 410 may not have a potential slope between the first surface 400a and the second surface 400b of the substrate 400.

The substrate 400 and the photoelectric conversion region 410 may form a photodiode. For example, a photodiode may be formed by a p-n junction between the substrate 400 of the first conductivity type and the photoelectric conversion region 410 of the second conductivity type. The photoelectric conversion region 410 constituting the photodiode may generate and accumulate photocharges in proportion to the intensity of the incident light.

Referring to FIG. 6 and FIG. 7, the separation pattern 450 may be positioned on the substrate 400. The separation pattern 450 may have a lattice structure in a plan view. The separation pattern 450 may partition each pixel in a plan view while also positioning between a plurality of photoelectric conversion devices PD1, PD2, PD3, PD4, PD5, PD6, PD7, and PD8 included in a single pixel.

Referring to FIG. 7, the separation pattern 450 may be positioned in the first trench TR1 and the second trench TR2. The first trench TR1 and the second trench TR2 may penetrate the substrate 400 or be sunk into the substrate 400 in some region of the first surface 400a of the substrate 400. As shown in FIG. 7, the first trench TR1 may be deeper than the second trench TR2. The separation pattern 450 may extend from the first surface 400a of the substrate 400 toward the second surface 400b. The separation pattern 450 may include the deep trench isolation layer DTI and the shallow trench isolation layer STI. The separation pattern 450 may penetrate the substrate 400. The vertical height of the separation pattern 450 may be substantially the same as the vertical thickness of the substrate 400. For example, the width of the separation pattern 450 may gradually decrease from the first surface 400a of the substrate 400 to the second surface 400b. However, this is an example and the disclosure is not limited to this. As another example, the width of the separation pattern 450 may gradually increase from the first side 400a of the substrate 400 to the second side 400b. In another example, the width of the separation pattern 450 may be constant between the first surface 400a and the second surface 400b of the substrate 400.

The separation pattern 450 may include a first separation pattern 451, a second separation pattern 453, and a third separation pattern 455. The first separation pattern 451 and the second separation pattern 453 may form the deep trench isolation layer DTI, and the third separation pattern 455 may form the shallow trench isolation layer STI.

The first separation pattern 451 may be positioned along the side wall of the first trench TR1. The first separation pattern 451 may include, for example, a silicon-based insulating material (e.g., silicon nitride, silicon oxide or silicon oxynitride) or a high dielectric material (e.g., hafnium oxide or aluminum oxide). As another example, the first separation pattern 451 may include a plurality of layers, and the plurality of layers may include different materials. The first separation pattern 451 may have a lower refractive index than the substrate 400. Accordingly, the crosstalk phenomenon between each photoelectric conversion region positioned on the substrate 400 may be prevented or minimized.

The second separation pattern 453 may be positioned in the first separation pattern 451. For example, the side wall of the second separation pattern 453 may be surrounded by the first separation pattern 451. The first separation pattern 451 may be positioned between the second separation pattern 453 and the substrate 400. The second separation pattern 453 may be separated from the substrate 400 by the first separation pattern 451. Accordingly, when the image sensor 100 operates, the second separation pattern 453 may be electrically separated from the substrate 400. The second separation pattern 453 may include a crystalline semiconductor material, for example, polycrystalline silicon. For example, the second separation pattern 453 may further include a dopant, and the dopant may include an impurity of the first conductivity type or an impurity of the second conductivity type.

For example, the second separation pattern 453 may include doped polycrystalline silicon. In another example, the second separation pattern 453 may include an undoped crystalline semiconductor material. For example, the second separation pattern 453 may comprise undoped polycrystalline silicon. The term “undoped” may indicate that no intentional doping process has been performed. The dopant may include an n-type dopant and a p-type dopant. However, the second separation pattern 453 may also include an insulating material.

The third separation pattern 455 may be positioned on the lower surface of the second separation pattern 453. The third separation pattern 455 may be positioned in the second trench TR2 and may be arranged adjacent to the first surface 400a of the substrate 400. The third separation pattern 455 may include a non-conductive material. As an example, the third separation pattern 455 may include a silicon-based insulating material (e.g., silicon nitride, silicon oxide or silicon oxynitride) or a high-dielectric material (e.g., hafnium oxide or aluminum oxide). Accordingly, the separation pattern 450 may prevent photocharges generated by incident light incident on the photoelectric conversion region 410 from being incident on another adjacent photoelectric conversion region due to random drift. For example, the separation pattern 450 may prevent or minimize the crosstalk phenomenon between the photoelectric conversion regions 410.

According to an embodiment, the first separation pattern 451 and the third separation pattern 455 may include the same material, in which case the boundary between the first separation pattern 451 and the third separation pattern 455 may not be visible and may appear to be connected together.

FIG. 7 illustrates a configuration in which the separation pattern 450 and the first surface 400a of the substrate 400 are positioned on the same plane, but this is an example, and the embodiment is not limited thereto. For example, the separation pattern 450 and the first surface 400a of the substrate 400 may not be coplanar or on the same plane. The separation pattern 450 may be protruded or recessed from the first surface 400a of the substrate 400.

In FIG. 7, the upper surface of the separation pattern 450 is depicted as flat, but this is an example, and the upper surface of the separation pattern 450 may include a curved surface. For example, the upper surface of the separation pattern 450 may be sunken or protruded toward the substrate 400.

The transmission transistor TG (e.g., TG1, TG2, TG3, TG4, TG5, TG6, TG6, TG7, and TG8) described in FIG. 2 may be positioned on the first surface 400a of the substrate 400. The transmission transistor TG may be electrically connected to the photoelectric conversion region 410. Referring to FIG. 6 and FIG. 7, a transmission transistor TG may include a gate electrode TRG and the floating diffusion region FD positioned on an active pattern ACT. FIG. 6 to FIG. 7 illustrate a configuration with two gate electrodes TRG, but this is an example and there may be a single gate electrode TRG.

The floating diffusion region FD may be adjacent to a side of the gate electrode TRG. The floating diffusion region FD may be positioned in the active pattern ACT. The floating diffusion region FD may have a second conductivity type (e.g., n-type) opposite to the substrate 400.

The first wire region 20 may be positioned on the first surface 400a of the substrate 400 and may include a plurality of insulation layers IL1, IL2, and IL3, a plurality of wiring layers CL1, and CL2, and a plurality of vias VIA.

The plurality of insulation layers IL1, IL2, and IL3 may include a first insulation layer IL1, a second insulation layer IL2, and a third insulation layer IL3.

The first insulation layer IL1 may cover the first surface 400a of the substrate 400. The first insulation layer IL1 may cover the gate electrode TRG. The second insulation layer IL2 may be positioned on the first insulation layer IL1. The third insulation layer IL3 may be positioned on the second insulation layer IL2.

The first to third insulation layers IL1, IL2, and IL3 may include a non-conductive material. For example, the first to third insulation layers IL1, IL2, and IL3 may include a silicon-based insulating material such as silicon oxide, silicon nitride or silicon oxynitride.

The plurality of wiring layers CL1 and CL2 may include the first wiring layer CL1 and the second wiring layer CL2. The first wiring layer CL1 may be positioned in the second insulation layer IL2. The second wiring layer CL2 may be positioned in the third insulation layer IL3.

Wires positioned in each of the first wiring layer CL1 and the second wiring layer CL2 may be connected to the floating diffusion region FD through the plurality of vias VIA. The plurality of vias VIA may penetrate the first to third insulation layers IL1, IL2, and IL3.

For example, the image sensor 100 according to an embodiment may include a light transmitting layer 30. The light transmitting layer 30 may include an insulating structure 329, a unit color filter 303, and a micro lens part 306. The light transmitting layer 30 may collect and filter light incident from the outside and provide the light to the photoelectric conversion region 410.

The unit color filter 303 may be positioned on the second surface 400b of the substrate 400. The color filter of the plurality of pixels PX arranged in N*M that absorb the same color may be positioned as a single color filter for the entire N*M pixel area, or as a separate color filter for each pixel PX. In this specification, the unit color filter 303 may include an integrated color filter covering the plurality of pixels PX that absorb the same color or an individual color filter arranged on each pixel PX.

The unit color filter 303 may include primary color filters. The unit color filter 303 may include a first color filter, a second color filter, and a third color filter having different colors. For example, the first color filter, second color filter, and third color filter may each include green, red, and blue color filters. The first color filter, second color filter, and third color filter may be arranged in a Bayer pattern. In another example, the first color filter, second color filter, and third color filter may have colors such as cyan, magenta, or yellow.

The insulating structure 329 may be positioned between the second surface 400b of the substrate 400 and the unit color filter 303. The insulating structure 329 may prevent reflection of light so that light incident on the second surface 400b of the substrate 400 may smoothly reach the photoelectric conversion region 410. The insulating structure 329 may be named an antireflection structure.

The insulating structure 329 may include a first fixed charge film 321, a second fixed charge film 323, and a planarization layer 325 sequentially laminated (or stacked) on a second surface 400b of the substrate 400. Each of the first fixed charge film 321, the second fixed charge film 323, and the planarization layer 325 may include different materials. The first fixed charge film 321 may include any one of aluminum oxide, tantalum oxide, titanium oxide, and hafnium oxide. The second fixed charge film 323 may include any one of aluminum oxide, tantalum oxide, titanium oxide, and hafnium oxide. For example, the first fixed charge film 321 may include aluminum oxide, the second fixed charge film 323 may include hafnium oxide, and the planarization layer 325 may include silicon oxide. In another embodiment, although not shown, a silicon anti-reflection layer may be interposed between the second fixed charge film 323 and the planarization layer 325. The anti-reflection layer may include silicon nitride.

A micro lens part 306 may be positioned on the unit color filter 303. The micro lens part 306 may include a flat portion 305 in contact with the unit color filter 303 and a micro lens 307 positioned on the flat portion 305. The flat portion 305 may, for example, include an organic material. As another example, the flat portion 305 may include silicon oxide or silicon oxynitride. The micro lens 307 may have a convex shape to focus incident light. Each micro lens 307 may vertically overlap the photoelectric conversion region 410. The shape of the micro lens 307 may vary. FIG. 7 shows, for descriptive convenience, a micro lens 307 in the shape of overlapping two photoelectric conversion regions 410 in the cross-section. However, in a plan view, one micro lens 307 may be positioned that overlaps four photoelectric conversion regions 410. However, this is an example, and the plurality of micro lenses 307 positioned on a pixel PX may vary.

The optically transparent layer 30 may further include a Bayer pattern 311 and a protective layer 316. The Bayer pattern 311 may be positioned between adjacent unit color filters 303 to separate them from each other. The Bayer pattern 311 may be positioned on the insulating structure 329. For example, the Bayer pattern 311 may have a lattice structure. The Bayer pattern 311 may include materials having a lower refractive index than the unit color filter 303. The Bayer pattern 311 may include an organic material. For example, the Bayer pattern 311 may be a polymer layer including silica nano particles. The Bayer pattern 311 may have a low refractive index, and may increase the amount of light incident on the photoelectric conversion region 410 and reduce crosstalk between pixels PX. For example, the light receiving efficiency may be increased in each photoelectric conversion region 410, and the signal-to-noise ratio (SNR) characteristic may be improved.

The protective layer 316 may cover the surface of the Bayer pattern 311 with a substantially uniform thickness. The protective layer 316 may include, for example, a single layer or a multilayer of at least one of an aluminum oxide layer and a silicon carbonization oxide layer. The protective layer 316 may protect the unit color filter 303 and absorb moisture. Although the protective layers 316 are depicted separately in FIG. 7, in an embodiment the protective layers 316 may be connected together between adjacent Bayer patterns 311.

Referring to FIG. 6 and FIG. 8, the arrangement of the dummy gate pattern DGP, the shield contact SC, and the connection contact CC is explained.

Referring to FIG. 6 and FIG. 8, the dummy gate pattern DGP may be positioned to overlap the separation pattern 450 in the third direction DR3. The dummy gate pattern DGP may be positioned between the neighboring pixels PX1 and PX2. A gate insulation layer GI may be positioned between the dummy gate pattern DGP and the separation pattern 450. The dummy gate pattern DGP may be connected to the voltage wire VL through the shield contact SC. As explained above, the ground voltage may be applied to the voltage wire VL and may be transmitted to the dummy gate pattern DGP and the dummy gate electrode DRG through the shield contact SC. The dummy transistor DG including the dummy gate electrode DRG to which the ground voltage is applied may function as an additional capacitor as described above. As shown in FIG. 8, the connection contact CC positioned in the first pixel area PX1 may be connected to the connection wire CL, and the connection contact CC positioned in the second pixel area PX2 may be connected to the connection wire CL. The shield contact SC may be positioned between adjacent connection contacts CC.

FIG. 9 describes the dummy transistor DG including the dummy gate pattern DGP for reference. Referring to FIG. 9, the overlap capacitance Cov may be formed at the part where the dummy gate electrode DRG to which the ground voltage is applied and the source region SA and the drain region DA of the active pattern ACT overlap. The overlap capacitance Cov may increase the overall capacitance of the image sensor 100. Referring to FIG. 9, a spacer SP may be positioned on the side of the dummy gate electrode DRG, and the gate insulation layer GI may be positioned between the dummy gate electrode DRG and the active pattern ACT. As will be explained separately later, the capacitance of the dummy transistor DG may be controlled by adjusting the thickness H2 of the gate insulation layer GI. The thickness H2 of the gate insulation layer GI included in the dummy transistor DG may be different from the thickness of the gate insulation layer GI included in other transistors.

Referring to FIG. 6, the active pattern ACT of the dummy transistor DG may be separated by the dummy gate electrode DRG. Therefore, as shown in FIG. 6 and FIG. 9, the connection contact CC and the connecting wire CL may be positioned to connect separate active patterns ACT. As shown in FIG. 6 and FIG. 9, the active pattern ACT separated by the dummy gate electrode DRG may be connected to the connection wire CL through the connection contact CC. Therefore, as shown in FIG. 6, the dummy transistor DG may be electrically connected to another transistor.

However, when voltage is applied through the connection contact CC, this operation may interfere with the operation of neighboring pixels PX. As the pixel size decreases with higher resolution, the distance between neighboring pixels PX may become shorter. For example, as shown in FIG. 6, when voltage is applied to the connection contact CC and the connection wire CL positioned in the first pixel area PX1, the connection contact CC positioned in the neighboring second pixel area PX2 may be interfered. This is a coupling that occurs when the distance between the first pixel area PX1 and the second pixel area PX2 becomes closer, and the normal operation of the image sensor 100 may become difficult due to this coupling. For example, switching or resetting the dual conversion transistor DCG may induce electrical interference in neighboring pixels PX. Therefore, it is necessary to ensure that the operation of the first pixel area PX1 does not interfere with the operation of the second pixel area PX2.

Accordingly, the image sensor 100 according to an embodiment may prevent coupling between different pixels PX by positioning the shield contact SC, which applies ground voltage to the dummy gate pattern DGP, between the connection contacts CC positioned at different pixels PX. For example, as explained above, as the ground voltage may be applied to the shield contact SC, coupling between neighboring pixels PX may be prevented through this shield contact SC.

Referring to FIG. 8, the configuration and effect of the image sensor 100 according to the embodiment are described. Referring to FIG. 8, the dummy gate pattern DGP and the shield contact SC may be positioned between the connection contact CC connected to the active pattern ACT of the first pixel area PX1 and the connection contact CC connected to the active pattern ACT of the second pixel area PX2. The shield contact SC may be positioned between the connection contacts CC of neighboring pixels PX and may prevent coupling between neighboring pixels PX.

As shown in FIG. 6 and FIG. 8, the shield contact SC may be positioned to overlap the separation pattern 450 in the third direction DR3, and may be positioned between neighboring pixels PX. However, this is an example, and a configuration in which a part of the shield contact SC overlaps or does not overlap the separation pattern 450 may also be included in the disclosure.

Referring to FIG. 6 and FIG. 8, the shield contact SC may be positioned on the same line as the connection contact CC of the neighboring pixels PX in the first direction DR1. Therefore, coupling of neighboring pixels PX may be effectively prevented. For example, as shown in FIG. 6 and FIG. 8, the shield contact SC may be positioned on a virtual straight line connecting the connection contact CC in the first pixel area PX1 and the connection contact CC in the second pixel area PX2.

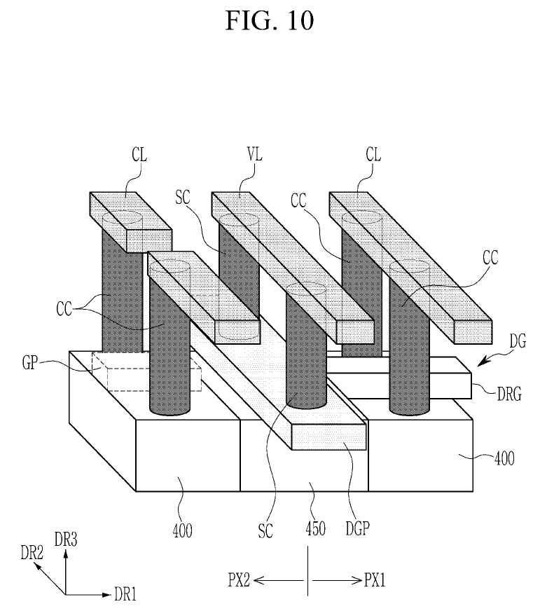

FIG. 10 is a simplified three-dimensional drawing of the structure of region R1 of FIG. 6. Referring to FIG. 10, the first pixel area PX1 and the second pixel area PX2 may be positioned with the separation pattern 450 between them. The connection contact CC and the connection wire CL may be positioned in the first pixel area PX1, and the connection contact CC and the connection wire CL may be positioned in the second pixel area PX2.

Referring to FIG. 10, the dummy gate pattern DGP may be positioned to overlap the separation pattern 450. The dummy gate pattern DGP may include the extension extending into the first pixel area PX1, and the extension may form a dummy gate electrode DRG. The dummy gate electrode DRG may form the dummy transistor DG. The dummy gate pattern DGP may be connected to the voltage wire VL through the shield contact SC. As explained above, the ground voltage may be applied to the dummy gate pattern DGP and the dummy gate electrode DRG through the voltage wire VL, and the dummy transistor DG may operate as an additional capacitor. As shown in FIG. 9, the shield contact SC may be positioned between adjacent connection contacts CC. Therefore, although a voltage is applied to the connection wire CL and the connection contact CC of the first pixel area PX1, coupling may be prevented from occurring in the connection wire CL and the connection contact CC of the second pixel area PX2.

For example, the image sensor 100 according to an embodiment uses the shield contact SC for applying the ground voltage to the dummy transistor DG between neighboring connection contacts CC, thereby simultaneously preventing coupling between neighboring pixels PX and utilizing the dummy transistor DG as an additional capacitor. For example, in the embodiment, the image sensor 100 may integrate a shield structure for preventing coupling of neighboring pixels PX and a contact for applying voltage to the dummy transistor DG. Therefore, the flat layout of the image sensor 100 may be efficiently configured, the pixel size may be reduced, and a high-resolution image sensor 100 may be implemented. For example, the image sensor 100 may effectively prevent coupling of neighboring pixels PX in a high-resolution image sensor, and may implement various combinations of conversion gains while increasing the entire capacitance of the image sensor 100 as the dummy transistor DG operates as an additional capacitor.

The arrangement and the connection form of the active pattern ACT, the gate pattern GP, and the dummy gate pattern DGP arranged in FIG. 6 are examples and the disclosure is not limited thereto. For example, various structures in which the dummy gate pattern DGP and the connected shield contact SC are positioned between the connection contacts CC of different pixels PX may be included in the disclosure.

For example, the shape of the dummy gate pattern DGP may be modified to allow the dummy transistor DG to have various capacitances. Various modifications embodiments are described below.

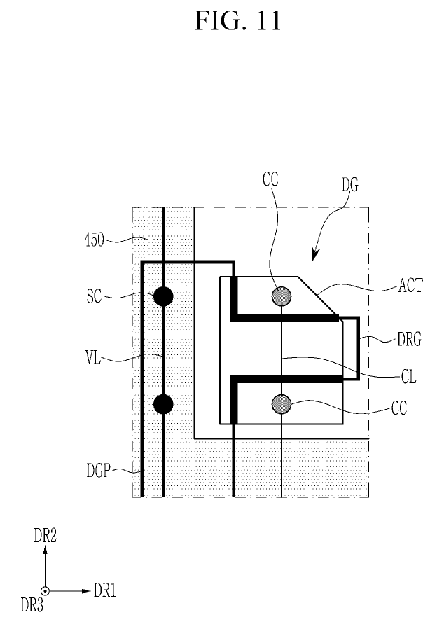

FIG. 11 is an enlarged view of region R2 of FIG. 6. As described above, the overlap capacitance Cov of the dummy transistor DG according to an embodiment may be formed at the interface of the dummy gate electrode DRG and the active pattern ACT. In FIG. 11 to FIG. 18, the region where the overlap capacitance Cov is formed is depicted with a thick line. The capacitance of the dummy transistor DG may be controlled by varying the length of the interface between the dummy gate electrode DRG and the active pattern ACT. The following describes a modified embodiment.

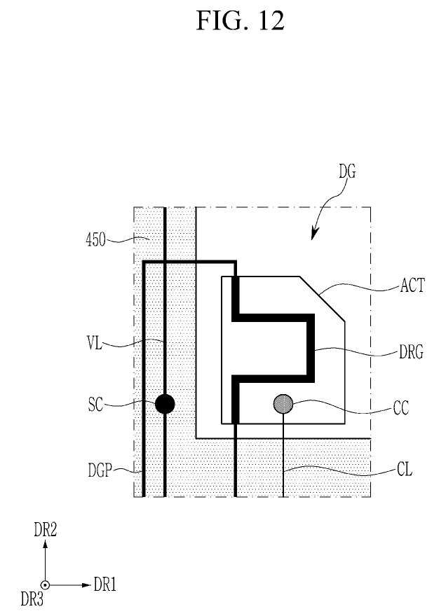

FIG. 12 illustrates the same region as FIG. 11 in the image sensor 100 according to another embodiment. Referring to FIG. 12, the image sensor 100 according to an embodiment is substantially identical to the embodiments of FIG. 6 and FIG. 11 except for the shape of the dummy gate electrode DRG and the arrangement of the connection contact CC and the shield contact SC. Redundant descriptions of the same components are omitted. Referring to FIG. 12, the dummy gate electrode DRG according to an embodiment may not separate the active pattern ACT. Therefore, unlike what is shown in FIG. 11, the active pattern ACT of the dummy transistor DG of FIG. 12 may be connected together (or integrated as a single body). Therefore, as shown in FIG. 11, the connection contact CC for connecting the active pattern ACT separated by the dummy gate electrode DRG may be omitted. Accordingly, in the embodiment of FIG. 12, the connection contact CC for applying voltage to the active pattern ACT may be positioned, and as the number of the connection contacts CC is reduced, the number of the shield contacts SC for shielding the connection contacts CC may also be reduced. In the embodiments below, the number of the neighboring connection contacts CC and the number of the shield contacts SC between different pixels PX may be the same. For example, the shield contact SC may be positioned between neighboring connection contacts CC in the first direction DR1 in different pixels PX, and the number of the neighboring connection contacts CC and the number of the shield contacts SC between different pixels PX may be the same.

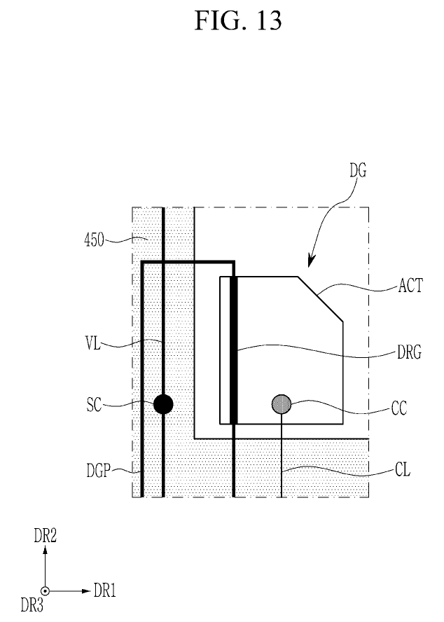

FIG. 13 illustrates the same region as FIG. 11 in the image sensor 100 according to another embodiment. Referring to FIG. 13, the image sensor 100 according to an embodiment is substantially identical to the embodiments of FIG. 6 and FIG. 11 except for the shape of the dummy gate pattern DGP and the arrangement of the connection contact CC and the shield contact SC. Redundant descriptions of the same components are omitted. Referring to FIG. 13, the dummy gate pattern DGP according to an embodiment may not include the extension. As shown in FIG. 13, the dummy gate pattern DGP may be positioned linearly, and the dummy gate pattern DGP overlapping the active pattern ACT may form the dummy gate electrode DRG. The configuration may reduce the length of the interface between the dummy gate electrode DRG and the active pattern ACT compared to FIG. 11. Therefore, the dummy transistor DG shown in FIG. 13 may have lower capacitance than that of FIG. 11. The shape of the dummy gate electrode DRG may be modified to allow the dummy transistor DG to have various capacitances.

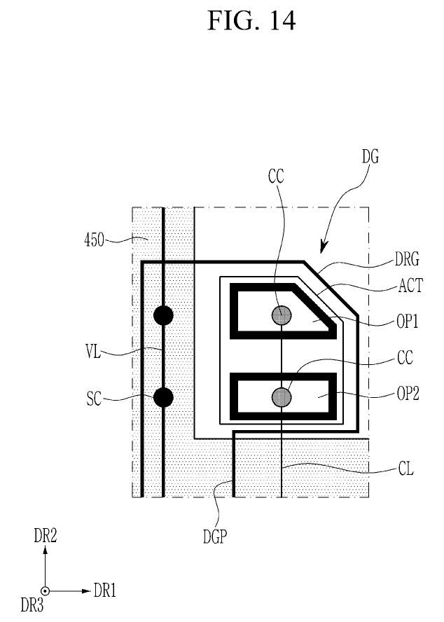

FIG. 14 illustrates the same region as FIG. 11 in the image sensor 100 according to another embodiment. Referring to FIG. 14, the image sensor 100 according to the embodiment is substantially identical to the embodiments of FIG. 6 and FIG. 11 except for the shape of the dummy gate electrode DRG and the arrangement of the connection contact CC and the shield contact SC. Redundant descriptions of the same components are omitted. Referring to FIG. 14, the image sensor 100 according to an embodiment may include the dummy gate electrode DRG having a planar area larger than the active pattern ACT. For example, the dummy gate electrode may include openings OP1 and OP2 that overlap the active pattern ACT. In the embodiment of FIG. 14, the overlap capacitance Cov may be formed at the interface of the dummy gate electrode DRG and the active pattern ACT, i.e., in the region indicated in bold in FIG. 14. The active patterns ACT positioned at each of the openings OP1 and OP2 may be separated from each other, and the separated active patterns ACT may be connected by the connection contact CC. The shield contact SC may be positioned parallel to the connection contact CC in the first direction DR1.

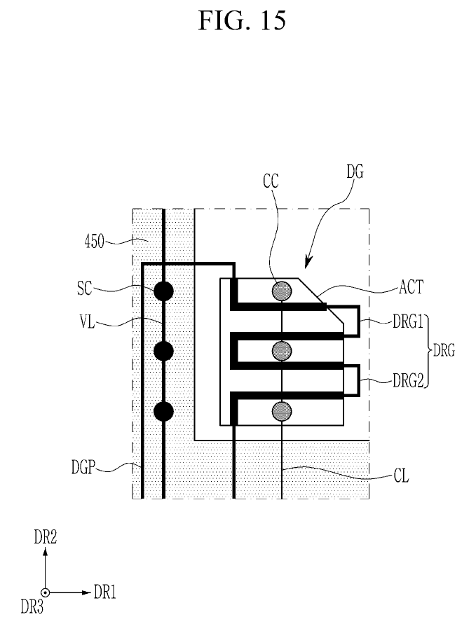

FIG. 15 illustrates the same region as FIG. 11 in the image sensor 100 according to another embodiment. Referring to FIG. 15, the image sensor 100 according to an embodiment is substantially identical to the embodiments of FIG. 6 and FIG. 11 except for the shape of the dummy gate electrode DRG and the arrangement of the connection contact CC and the shield contact SC. Redundant descriptions of the same components are omitted. Referring to FIG. 15, the image sensor 100 according to an embodiment may include the dummy gate electrode DRG including two extensions DRG1 and DRG2. Therefore, the length of the interface of the dummy gate electrode DRG and the active pattern ACT may be increased, and the overlap capacitance Cov may be increased. In the embodiment of FIG. 15, the active pattern ACT may be divided into three parts by the two extensions DRG1 and DRG2 of the dummy gate electrode DRG, and three connection contacts CC may be included to connect the three connection contacts. In the embodiment of FIG. 15, the three connection contacts CC may be positioned, and three shield contacts SC may also be positioned. For example, the three shield contacts SC may be positioned parallel to the three connection contacts CC and may be spaced apart from the three connection contacts CC in the first direction DR1. As explained above, the number of the neighboring connection contacts CC and the number of the shield contacts SC between different pixels PX may be the same. The image sensor 100 according to an embodiment may include the three connection contacts CC and may also include the three shield contacts.

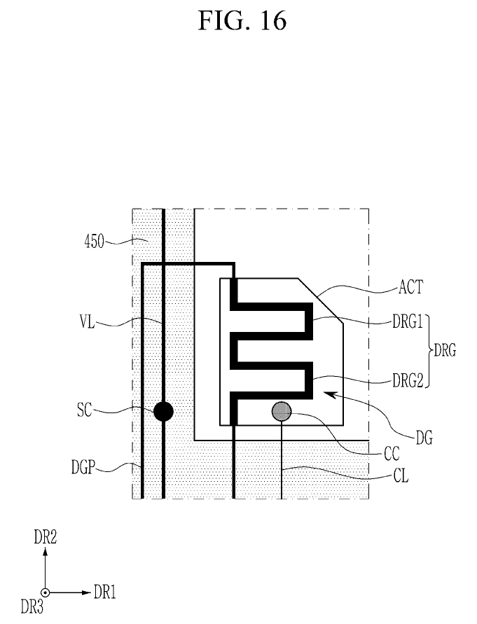

FIG. 16 illustrates the same region as FIG. 15 in the image sensor 100 according to another embodiment. Referring to FIG. 16, the image sensor 100 according to an embodiment is substantially identical to the embodiment of FIG. 15 except for the shape of the dummy gate electrode DRG and the arrangement of the connection contact CC and the shield contact SC. Redundant descriptions of the same components are omitted. Referring to FIG. 16, the image sensor 100 according to an embodiment may have the dummy gate electrode DRG in which the two extensions DRG1 and DRG2 may not completely separate the active pattern ACT. For example, since the active pattern ACT of the dummy transistor DG is not separated by the dummy gate electrode DRG, the connection contact CC for connecting the active patterns ACT separated by the dummy gate electrode DRG may be omitted. Therefore, the embodiment of FIG. 16 may include the connection contact CC, and as the number of the connection contacts CC is reduced, the number of the shield contacts SC to shield it may also be reduced.

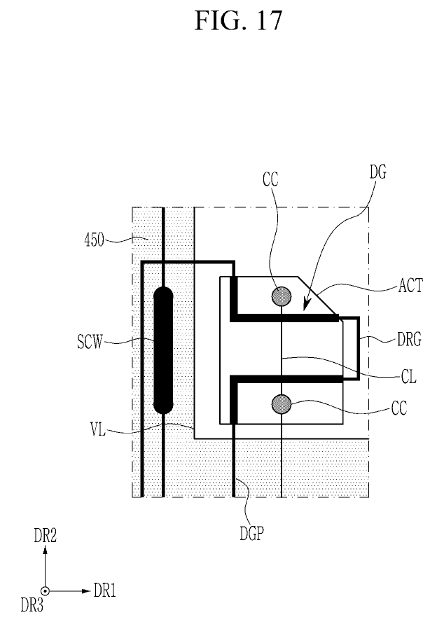

FIG. 17 illustrates the same region as FIG. 11 in the image sensor 100 according to another embodiment. Referring to FIG. 17, the image sensor 100 according to the embodiment is substantially identical to the embodiments of FIG. 6 and FIG. 11 except for the shape of the shield contact SC. Redundant descriptions of the same components are omitted. Referring to FIG. 17, in the embodiment, the shield contact SC may be formed as a shield contact wall SCW, which is a wall shape extending along a direction (e.g., second direction DR1). For example, in the previous embodiment, the shield contact SC may be in the form of a column as shown in FIG. 10, but in the embodiment of FIG. 17, the shield contact wall SCW may be positioned in the form of a wall extending along the second direction DR2. For example, coupling between neighboring pixels PX may be prevented more effectively.

Although various embodiments are described in FIG. 11 to FIG. 17, these are examples and the disclosure is not limited thereto. The shape of the dummy gate pattern DGP, dummy gate electrode DRG, and the arrangement of the connection contact CC and the shield contact SC may vary according to embodiments.

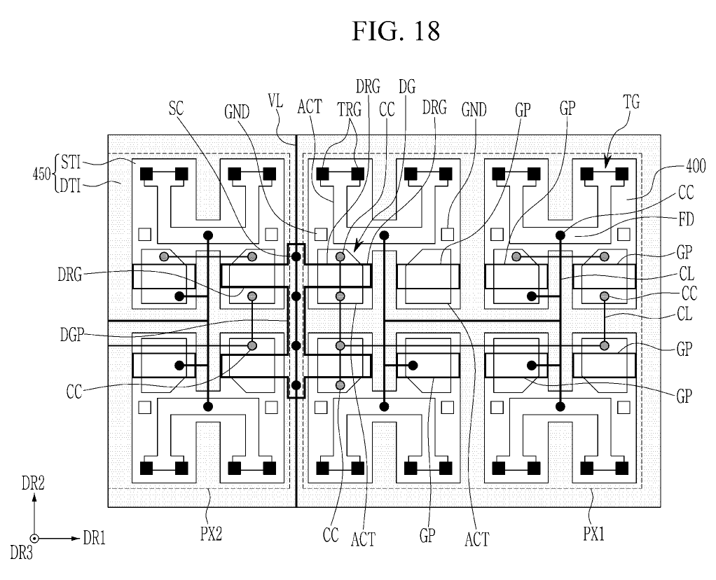

FIG. 18 illustrates the same region as FIG. 6 in the image sensor 100 according to another embodiment. Referring to FIG. 18, the image sensor 100 according to an embodiment is substantially identical to FIG. 6 except for the shape of the dummy gate electrode DRG. Redundant descriptions of the same components are omitted. Referring to FIG. 18, in the image sensor 100 according to an embodiment, the dummy gate electrode DRG may be positioned symmetrically with respect to the first pixel area PX1 and the second pixel area PX2, using the center of the separation pattern 450 as a reference. For example, in the embodiment of FIG. 6, the dummy gate electrode DRG may extend to overlap the active pattern ACT of the first pixel area PX1 and may not extend in the direction of the second pixel area PX2. However, in the embodiment of FIG. 18, the dummy gate electrode DRG may be positioned to overlap both the active pattern ACT positioned in the first pixel area PX1 and the active pattern ACT positioned in the second pixel area PX2. As shown in FIG. 18, the dummy gate electrode DRG may be positioned symmetrically in the first pixel area PX1 and the second pixel area PX2. However, this is an example and the disclosure is not limited thereto.

For example, the dummy gate pattern DGP according to an embodiment may be electrically connected to the ground pattern GND so that the ground voltage may be applied to the ground pattern GND. In the embodiments of FIG. 6 and FIG. 18, the dummy gate pattern DGP may overlap the active pattern ACT, but may not overlap the ground pattern GND. However, in another embodiment, the dummy gate pattern DGP may overlap the ground pattern GND, and the ground voltage may be applied to the ground pattern GND.

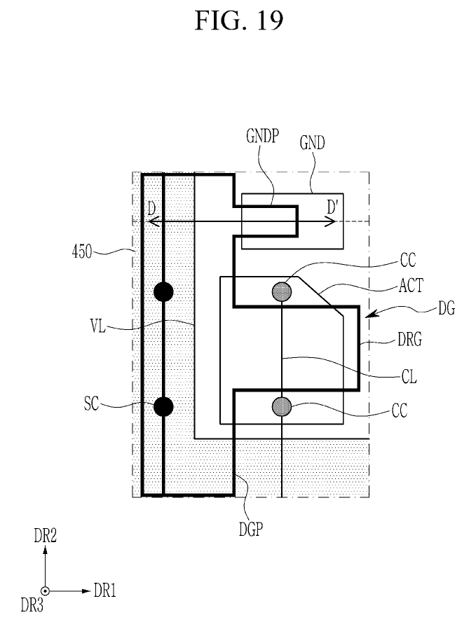

FIG. 19 illustrates region R3 of FIG. 6 for another embodiment. Referring to FIG. 19, the dummy gate pattern DGP according to an embodiment may include the dummy gate electrode DRG that overlaps an active pattern ACT and a ground voltage application pattern GNDP that overlaps a ground pattern. For example, one of the two extensions protruded from the dummy gate pattern DGP in the first direction DR1 may form the dummy gate electrode DRG and the other may form the ground voltage application pattern GNDP. The ground voltage application pattern GNDP may apply the ground voltage to the ground pattern GND. For example, in the case of the image sensor 100 having a structure like FIG. 19, the ground voltage may be applied simultaneously to the ground pattern GND and the dummy transistor DG. However, the structure of FIG. 19 is an example, and the ground pattern GND may receive the ground voltage through a separate wire.

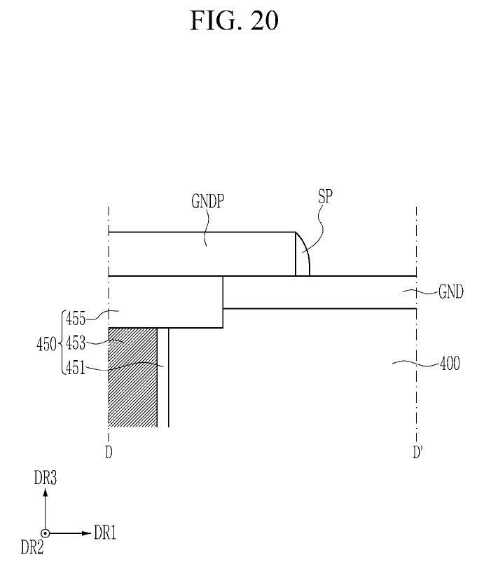

FIG. 20 is a cross-section of FIG. 19 taken along line D-D'. Referring to FIG. 20, the ground voltage application pattern GNDP may make direct contact with the ground pattern GND. For example, as shown in FIG. 20, the gate insulation layer GI may not be positioned between the ground voltage application pattern GNDP and the ground pattern GND, and voltage may be applied directly to the ground pattern GND.

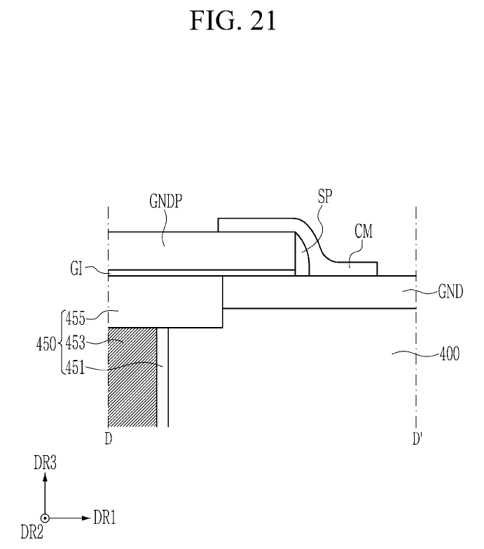

FIG. 21 illustrates the same region as FIG. 20 for another embodiment. Referring to FIG. 21, in the image sensor 100 according to an embodiment, the ground voltage application pattern GNDP may not be in direct contact with the ground pattern GND. For example, the gate insulation layer GI may be positioned between the ground voltage application pattern GNDP and the ground pattern GND. As shown in FIG. 21, a separate conductive connecting member CM may be positioned on the upper surface of the ground pattern GND, and the ground pattern GND and the ground voltage application pattern GNDP may be electrically connected through the conductive connecting member CM.

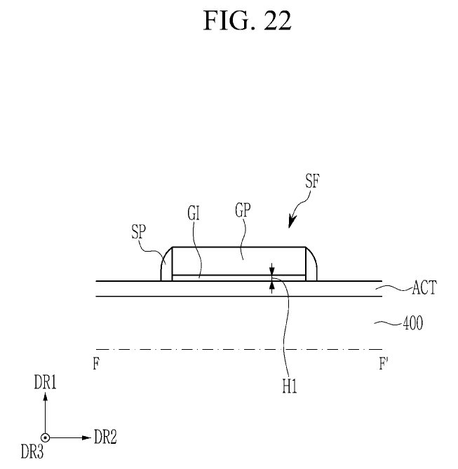

In an embodiment, the thickness of the gate insulation layer GI of the dummy transistor DG and another transistor may be different. FIG. 22 is a cross-sectional view taken along line E-E' of FIG. 6. In an embodiment, the transistor illustrated in FIG. 22 may be a source follower transistor. However, the disclosure is not limited thereto. The thickness H1 of the gate insulation layer GI of the transistor illustrated in FIG. 22 may be different from the thickness H2 of the gate insulation layer GI of the dummy transistor DG illustrated in FIG. 9. For example, the thickness H2 of the gate insulation layer GI of the dummy transistor DG may be thinner than the thickness H1 of the gate insulation layer GI of another transistor. For example, the thickness H2 of the gate insulation layer GI of the dummy transistor DG may be formed thinner to secure high capacitance. The dummy transistor DG may have a gate voltage that is always fixed to the ground voltage, so it may have a small voltage stress and may implement a thin gate insulation layer. High capacitance may be secured through a thin gate insulation layer GI.

However, this is just an example, and according to the required capacitance of the dummy transistor DG, the thickness H2 of the gate insulation layer GI of the dummy transistor DG may be formed thicker than the thickness H1 of the gate insulation layer GI of the other transistor. For example, the capacitance of the dummy transistor DG may be controlled by controlling the thickness of the gate insulation layer GI of the dummy transistor DG.

As described above, the image sensor 100 according to the embodiment may have the shield contact SC for applying the ground voltage to the dummy transistor DG placed between adjacent connection contacts CC. Therefore, coupling between neighboring pixels PX may be prevented by simultaneously utilizing the dummy transistor DG as an additional capacitor. By integrating the shield structure for preventing coupling of neighboring pixels PX and the contact for applying voltage to the dummy transistor DG into one, a high-resolution image sensor that may be driven by a variety of combinations of conversion gains may be implemented, and coupling of neighboring pixels PX in a high-resolution image sensor may be prevented.

Although an embodiment has been described in detail above, the scope of the disclosure is not limited thereto, and various modifications and improvements made by a person of an ordinary skill in the art using the basic concept of the disclosure defined in the following claims also fall within the scope of the disclosure.

What is claimed is:

1. An image sensor comprising
a substrate comprising a plurality of photoelectric conversion regions;
a separation pattern between the plurality of photoelectric conversion regions and separating the substrate;
a plurality of active patterns on the substrate;
a plurality of gate patterns overlapping the plurality of active patterns;
a connection contact connected to the plurality of active patterns or the plurality of gate patterns;
a dummy gate pattern overlapping the separation pattern; and
a shield contact connected to the dummy gate pattern,
wherein the shield contact and the connection contact are in parallel in a first direction.

2. The image sensor of claim 1, further comprising
a first pixel area and a second pixel area that are separated by the separation pattern, each of the first pixel area and the second pixel area comprising a plurality of photoelectric conversion regions,
wherein the dummy gate pattern overlaps the separation pattern between the first pixel area and the second pixel area.

3. The image sensor of claim 2, wherein the shield contact is between the connection contact in the first pixel area and the connection contact in the second pixel area.

4. The image sensor of claim 3, wherein the shield contact is on an imaginary straight line connecting the connection contact in the first pixel area and the connection contact in the second pixel area.

5. The image sensor of claim 2, wherein the dummy gate pattern comprises an extension protruding in the first pixel area, and
wherein sides of the dummy gate pattern are asymmetrical with respect to a center of the separation pattern.

6. The image sensor of claim 2, wherein the dummy gate pattern comprises an extension protruding in the first pixel area and the second pixel area, and
wherein sides of the dummy gate pattern are symmetrical with respect to a center of the separation pattern.

7. The image sensor of claim 1, wherein the dummy gate pattern comprises a dummy gate electrode overlapping a corresponding active pattern, and
wherein the dummy gate electrode and the corresponding active pattern overlapping the dummy gate electrode form a dummy transistor.

8. The image sensor of claim 7, wherein the dummy gate electrode is configured to receive a ground voltage, and
wherein the dummy transistor functions as a capacitor

9. The image sensor of claim 1, further comprising:
a ground pattern on the substrate,
wherein the dummy gate pattern comprises a ground voltage application pattern overlapping the ground pattern.

10. The image sensor of claim 9, wherein the ground voltage application pattern is in direct contact with the ground pattern.

11. The image sensor of claim 9, wherein an insulating film is between the ground voltage application pattern and the ground pattern, and
wherein the ground voltage application pattern is connected to the ground pattern through a connecting member.

12. The image sensor of claim 1, wherein a thickness of a gate insulating film between the plurality of active patterns and the plurality of gate patterns is different from a thickness of the gate insulating film between the plurality of active patterns and the dummy gate pattern.

13. The image sensor of claim 1, wherein a thickness of a gate insulating film between the plurality of active patterns and the plurality of gate patterns is greater than a thickness of the gate insulating film between the plurality of active patterns and the dummy gate pattern.

14. The image sensor of claim 1, wherein the shield contact has a wall shape extending in a second direction.

15. An Image sensor comprising:
substrate; and
a plurality of pixels on the substrate and separated by a separation pattern,
wherein each pixel comprises:
a plurality of photoelectric conversion regions;
a plurality of transfer transistors connected to the plurality of photoelectric conversion regions;
a dummy transistor comprising a gate electrode configured to receive a ground voltage; and
a shield contact connected to the gate electrode of the dummy transistor, and
wherein the shield contact overlaps the separation pattern between the plurality of pixels.

16. The image sensor of claim 15, wherein each pixel further comprises a plurality of transistors and connection contacts connected to the plurality of transistors, and
wherein the shield contacts are at different pixels in a plan view.

17. The image sensor of claim 15, wherein the dummy transistor further comprises an active pattern and a connection contact connected to the active pattern, and
wherein the connection contact and the shield contact are in parallel in a direction.

18. An Image sensor comprising:
a substrate comprising a photoelectric conversion region;
a plurality of transistors on the substrate and comprising dummy transistors;
a connection contact connected to the plurality of transistors; and
a shield contact connected to a gate electrode of each dummy transistor,
wherein the shield contact is configured to apply a ground voltage to the gate electrode of each dummy transistor, and
wherein the connection contact and the shield contact are in parallel in a direction.

19. The image sensor of claim 18, wherein the substrate comprises a separation pattern that divides a plurality of pixels, and
wherein the shield contact overlaps the separation pattern.

20. The image sensor of claim 18, wherein a thickness of a gate insulating film of the dummy transistor is different from a thickness of a gate insulating film of a transistor other than the dummy transistor.
